(19) United States
(12) Patent Application Publication
(10) Pub. No.: US 2014/0103984 A1
(43) Pub. Date: Apr. 17, 2014

(54) QUADRATURE SYMMETRIC CLOCK SIGNAL GENERATION

(71) Applicant: QUALCOMM INCORPORATED, San Diego, CA (US)

(72) Inventors: Jeremy Mark Goldblatt, Encinitas, CA (US); Sameer V. Vora, San Diego, CA (US)

(73) Assignee: QUALCOMM INCORPORATED, San Diego, CA (US)

(21) Appl. No.: 13/654,328

(22) Filed: Oct. 17, 2012

(51) Int. Cl. H03K 5/15

(52) U.S. Cl. 327/254

(57) ABSTRACT

Exemplary embodiments are directed to systems, methods, and devices for generating quadrature clock signals. A device may include a plurality of dynamic logic cells and a plurality of inverters. Each inverter of the plurality of inverters may be coupled to at least two dynamic logic cells of the plurality of dynamic logic cells. Each inverter may be configured to output a twenty-five percent duty cycle clock signal.

### BACKGROUND

1. Field

The present invention relates generally to clock signal generation. More specifically, the present invention relates to systems, devices, and methods for generating quadrature symmetric clock signals.

2. Background

As user equipment devices, such as wireless communication devices, become more sophisticated, minimizing power consumption becomes increasingly important. As will be understood by a person having ordinary skill in the art, a wireless communication device may include one or more local oscillator (LO) paths. More specifically, a wireless communication device, such as a mobile telephone, may include a transmitter having a LO path for converting a baseband signal to a radio frequency (RF) signal for transmission.

Further, a wireless communication device may include a receiver having a LO path for converting a received RF signal to a baseband signal for subsequent processing. LO paths may process an output of an oscillator to generate a desired output. This processing may consume relatively large amounts of current, thus reducing battery life of a communication device. Many wireless communication devices need one particular type of LO path having frequency dividers that generate twenty-five percent duty cycle in-phase and quadrature signals for subsequent processing in the transmitter or receiver. Conventional twenty-five percent duty-cycle local oscillator (LO) paths suffer from high power consumption (i.e., >>CV²f) due to static current in frequency dividers and/or short circuit current dissipated in associated buffers & logic.

Frequency dividers may be used for generating quadrature clock signals, which may be conveyed to a mixer within an LO path. Further, frequency dividers may be based on conventional high-speed digital flip-flops. However, digital flip-flops may not provide signals with a twenty-five percent duty cycle and may suffer from excessive power dissipation due to short-circuit current during switching. In addition, many known analog frequency dividers consume static current.

Many analog circuits are formed from standard cell libraries, which include specific building block circuit functions. One such standard cell library is known as a True Single-Phase Clock (TSPC) standard cell. Moreover, although true single-phase clock (TSPC) logic may be used for dividers, TSPC flip-flops may not be able to generate differential quadrature clock signals having a twenty-five percent duty cycle and, therefore, TSPC logic may be unusable for mixer applications that require a twenty-five percent duty cycle.

A need exists for improved methods, systems, and devices for generating quadrature clock signals having a twenty-five percent duty cycle.

### BRIEF DESCRIPTION OF THE DRAWINGS

FIG. 1 illustrates a true single-phase clock circuit.

FIG. 2 illustrates another example of a true single-phase clock circuit.

FIG. 3 is a schematic of a true single-phase clock circuit configured for outputting a plurality of internal voltages, in accordance with an exemplary embodiment of the present invention.

FIG. 4 is a device including a plurality of dynamic logic cells coupled to a conversion unit, according to an exemplary embodiment of the present invention.

FIG. 5 illustrates a plurality of dynamic logic cells coupled to a plurality of static buffers, in accordance with an exemplary embodiment of the present invention.

FIG. 6 illustrates a plurality of dynamic logic cells coupled to a plurality of static inverters, in accordance with an exemplary embodiment of the present invention.

FIG. 7 illustrates a plurality of dynamic logic cells coupled to a plurality of dynamic inverters, in accordance with an exemplary embodiment of the present invention.

FIG. 8A illustrates a circuit diagram of a dynamic inverter.

FIG. 8B is a plot illustrating various example waveforms associated with a dynamic inverter.

FIG. 9 illustrates a device including a plurality of dynamic logic cells coupled to a conversion unit and an initialization unit, according to an exemplary embodiment of the present invention.

FIG. 10 illustrates an initialization unit for initializing values of a plurality of nodes of a plurality of dynamic logic cells, according to an exemplary embodiment of the present invention.

FIG. 11 is a plot illustrating various waveforms that may be utilized by a PMOS and/or an NMOS driver.

FIG. 12 is a timing plot illustrating various waveforms associated with clock generation device.

FIG. 13 is a block diagram of a transceiver including a transmitter and a receiver, according to an exemplary embodiment of the present invention.

FIG. 14 is a block diagram of a wireless device, in accordance with an exemplary embodiment of the present invention.

FIG. 15 is a flowchart illustrating a method, in accordance with an exemplary embodiment of the present invention.

FIG. 16 is a flowchart illustrating another method, according to an exemplary embodiment of the present invention.

### DETAILED DESCRIPTION

The detailed description set forth below in connection with the appended drawings is intended as a description of exemplary embodiments of the present invention and is not intended to represent the only embodiments in which the present invention can be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. It will be apparent to those skilled in the art that the exemplary embodiments of the invention may be practiced without these specific details. In some instances, well-known structures and devices are shown in block diagram form in order to avoid obscuring the novelty of the exemplary embodiments presented herein.

A local oscillator (LO) may be used in an electronic device (e.g., a mobile device) to convert a particular signal to a different frequency. For example, a high frequency signal may be converted to a lower, baseband signal or vice versa using an LO. In addition to an oscillator, such as a voltage controlled oscillator (VCO), an LO may include an LO path that may include one or more buffers, frequency dividers, and mixers.

As will be appreciated by a person having ordinary skill in the art, various standard logic blocks have been used for circuit design. One such standard logic block is TSPC logic. TSPC logic has been used to create, for example, logic functions such as flip-flops. However, when, for example, a toggle type (T-type) of flip-flop constructed out of TSPC logic is used as a frequency divider in attempting to create a clock signal, the resulting output is not differential quadrature and it also does not exhibit a twenty-five percent duty cycle, and is therefore unusable as a clock for mixer applications that requires differential quadrature LO signals with twenty-five percent duty cycle.

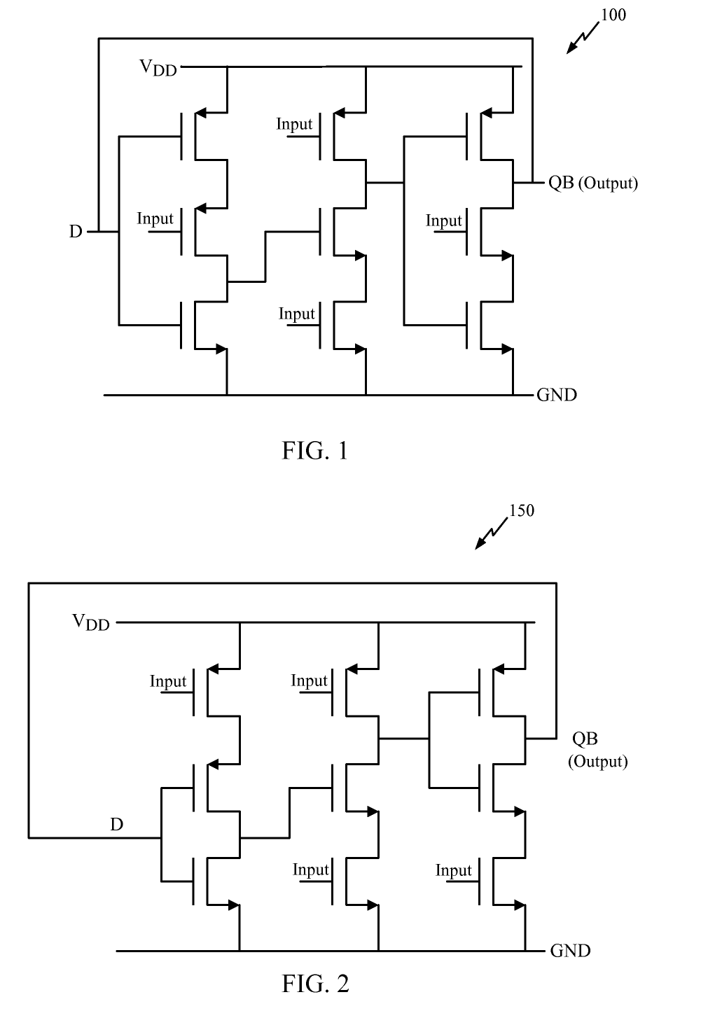

FIG. 1 is a circuit diagram of a TSPC flip-flop based frequency divider 100. FIG. 2 is a circuit diagram of another TSPC flip-flop based frequency divider 150. Neither divider 100 and nor divider 150 offers twenty-five percent duty cycles or differential quadrature outputs. In addition, as noted above, other frequency dividers based on conventional high-speed digital flip-flops may not offer twenty-five percent duty cycles and, furthermore, may suffer from power losses due to short-circuit current during switching.

According to various exemplary embodiments of the present invention, one or more internal nodes of a plurality of dynamic logic flip-flops may be utilized to generate differential quadrature LO signals with twenty-five percent duty cycle. More specifically, according to one exemplary embodiment, at least one internal voltage of each TSPC cell of a plurality of TSPC cells may be utilized to drive either dynamic or static inverters or buffers, which further drive one or more switches within a mixer in differential quadrature fashion with twenty-five percent duty cycle

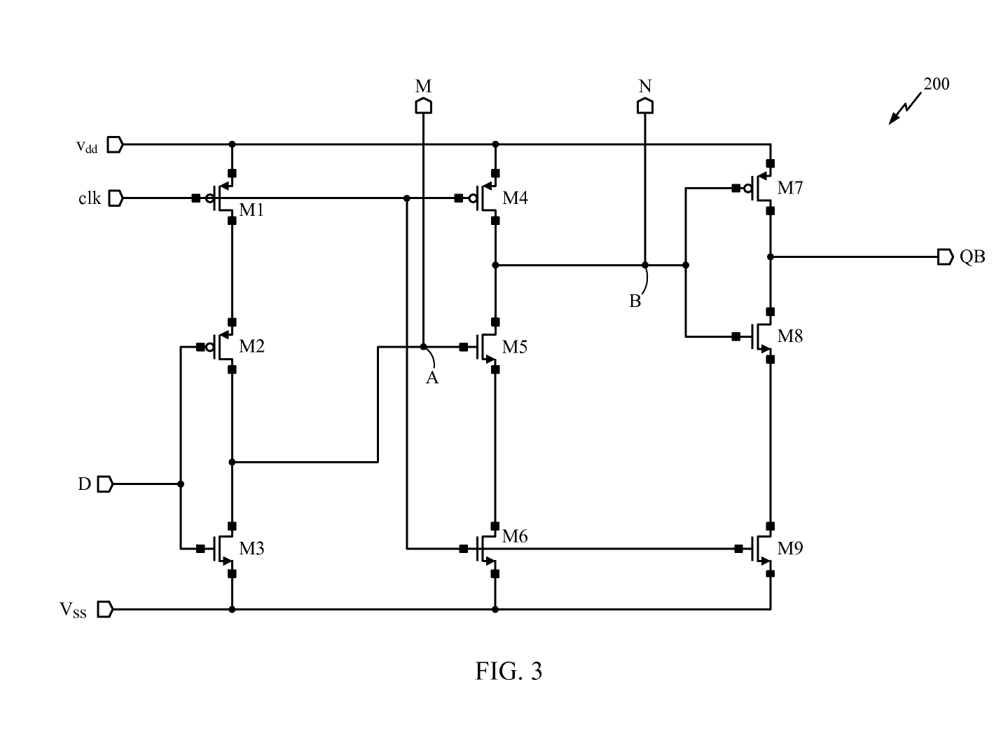

FIG. 3 is a schematic of a TSPC cell 200 including a plurality of transistors M1-M9. TSPC cell 200 is configured to receive a supply voltage V_{dd}, a clock signal clk, an input signal D, and a ground voltage vₛₛ. Further, TSPC cell 200 is configured to convey an output QB (i.e., Q̅ or “Qbar”). According to one exemplary embodiment of the present invention, TSPC 200 may include an output M, which is coupled to a node A. Node A may comprise a voltage internal to TSPC cell 200. Further, TSPC 200 may include another output N, which is coupled to node B. Node B may comprise a voltage internal to TSPC cell 200. Accordingly, output M may convey an internal voltage of TSPC cell 200 and output N may convey another internal voltage of TSPC cell 200.

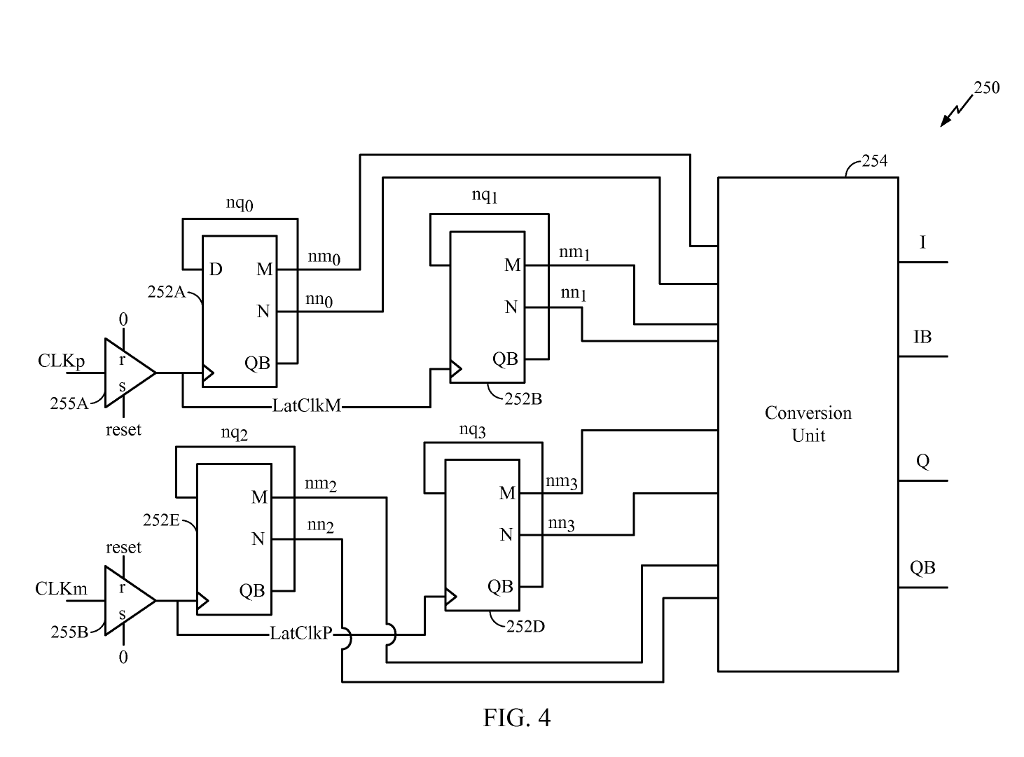

FIG. 4 illustrates a device 250 including a plurality of dynamic logic cells 252A-D coupled to a conversion unit 254, according to an exemplary embodiment of the present invention. Each dynamic logic cell 252A-D may include output M, output N, and an output QB. By way of example only, each dynamic logic cell 252A-D may comprise TSPC cell 200 illustrated in FIG. 3. Accordingly, an output M of each dynamic logic cell 252A-D may correspond to output M of TSPC 200. Further, an output N of each dynamic logic cell 252A-D may correspond to output N of TSPC 200.

As illustrated in FIG. 4, output M and output N of each dynamic logic cell 252A-D may be coupled to conversion unit 254. More specifically, dynamic logic cell 252A may be configured to convey a signal nm₀ and a signal nn₀ to conversion unit 254 via respective outputs M and N. Further, dynamic logic cell 252B may be configured to convey a signal nm₁ and a signal nn₁ to conversion unit 254 via respective outputs M and N. In addition, dynamic logic cell 252C may be configured to convey a signal nm₂ and a signal nn₂ to conversion unit 254 via respective outputs M and N. Moreover, dynamic logic cell 252D may be configured to convey a signal nm₃ and a signal nn₃ to conversion unit 254 via respective outputs M and N.

In addition, each dynamic logic cell 252A-D includes an input signal D and a clock input LatClk. As illustrated in FIG. 4, output QB of each dynamic logic cell 252 may be conveyed to an associated input D. Device 250 further includes a gating buffer 255A configured to receive a clock signal CLKp and a gating buffer 255B configured to receive a clock signal CLKm. Each of gating buffer 255A and gating buffer 255B is also configured to receive a reset signal “reset.” Gating buffer 255A is configured to convey clock signal LatClkM to each of TSPC cells 252A and 252B and gating buffer 255B is configured to convey a clock signal LatClkP to each of TSPC cells 252C and 252D.

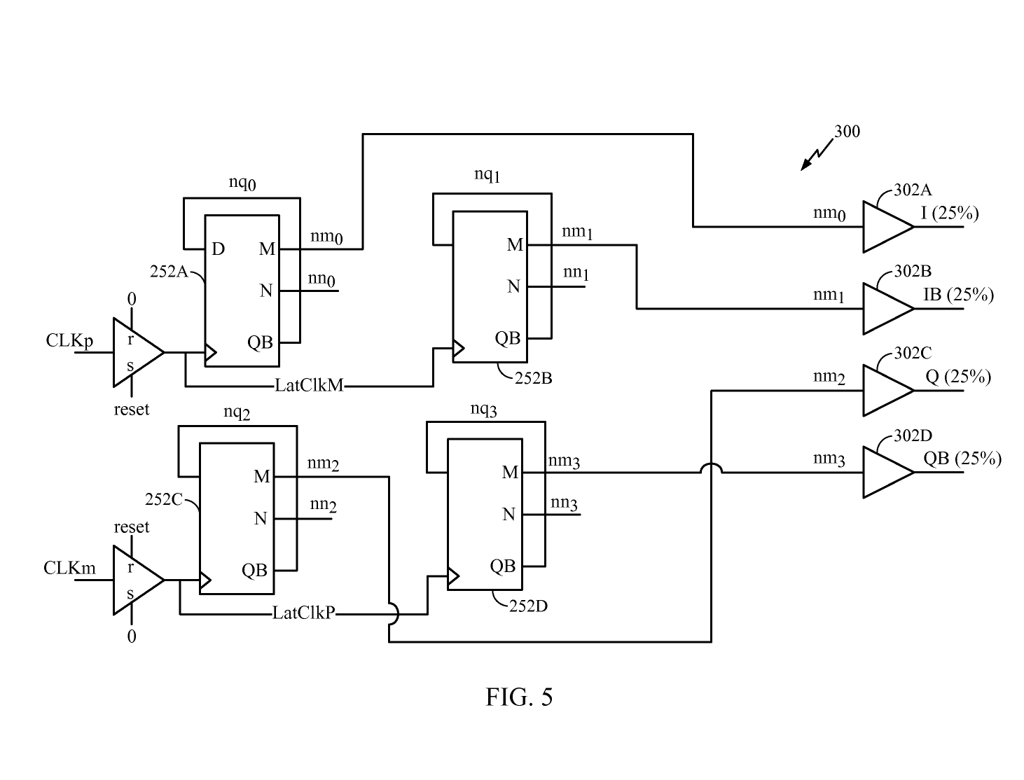

FIG. 5 depicts another device 300, in accordance with an exemplary embodiment of the present invention. Device 300 includes dynamic logic cells 252A-D coupled to a plurality of static buffers 302A-302D. More specifically, device 300 includes a static buffer 302A configured to receive a signal nm₀ from dynamic logic cell 252A and convey clock signal I having a twenty-five percent duty cycle. In addition, device 300 includes a static buffer 302b configured to receive a signal nm₁ from dynamic logic cell 252B and convey a clock signal IB (i.e., Ī or “Ibar”) having a twenty-five percent duty cycle. As will be appreciated by a person having ordinary skill in the art, clock signal IB may be offset 180 degrees from clock signal I. Moreover, device 300 includes a static inverter 302C configured to receive a signal nm₂ from dynamic logic cell 252C and convey a clock signal Q having a twenty-five percent duty cycle. Furthermore, device 300 includes a static buffer 302D configured to receive a signal nm₃ from dynamic logic cell 252D and convey a clock signal QB having a twenty-five percent duty cycle. As will be appreciated by a person having ordinary skill in the art, clock signal QB may be 180 degrees from and in-phase with clock signal Q. Further, clock signal Q may be 90 degrees out of phase from clock signal I.

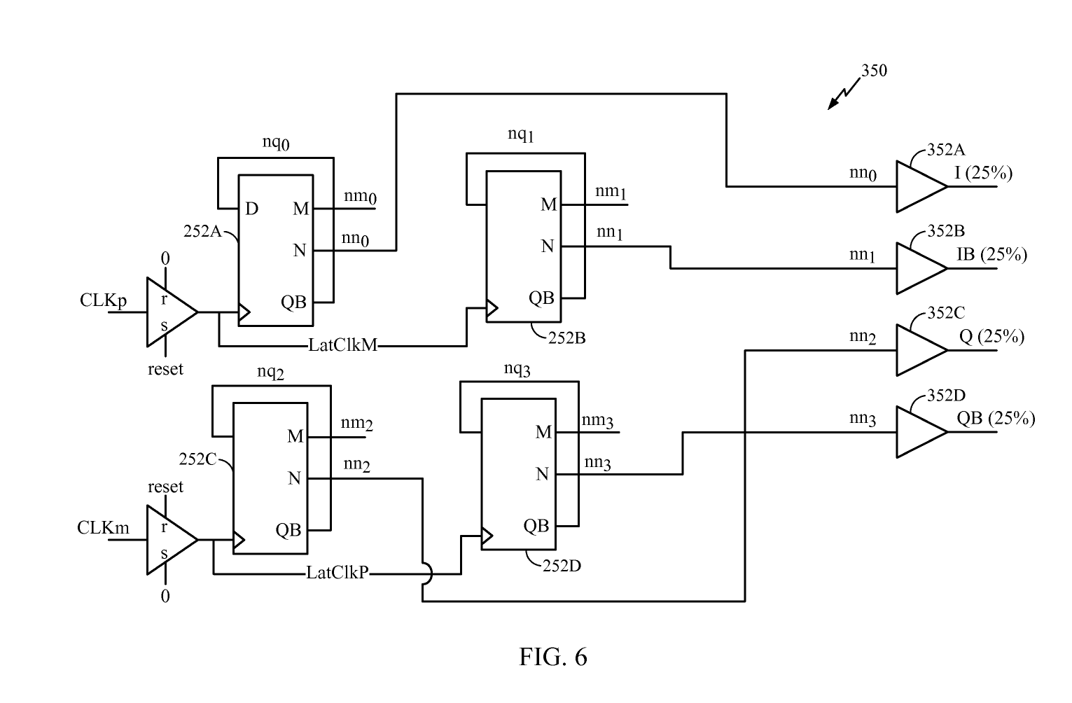

FIG. 6 depicts another device 350, in accordance with an exemplary embodiment of the present invention. Device 350 includes dynamic logic cells 252A-D coupled to a plurality of static inverters 352A-352D. More specifically, device 350 includes a static inverter 352A configured to receive a signal nn₀ from dynamic logic cell 252A and convey a clock signal I having a twenty-five percent duty cycle. In addition, device 300 includes a static inverter 352b configured to receive a signal nn₁ from dynamic logic cell 252B and convey a clock signal IB having a twenty-five percent duty cycle. Moreover, device 300 includes a static inverter 352C configured to receive a signal nn₂ from dynamic logic cell 252C and convey a clock signal Q having a twenty-five percent duty cycle. Furthermore, device 300 includes a static inverter 352D configured to receive a signal nn₃ from dynamic logic cell 252D and convey a clock signal QB having a twenty-five percent duty cycle.

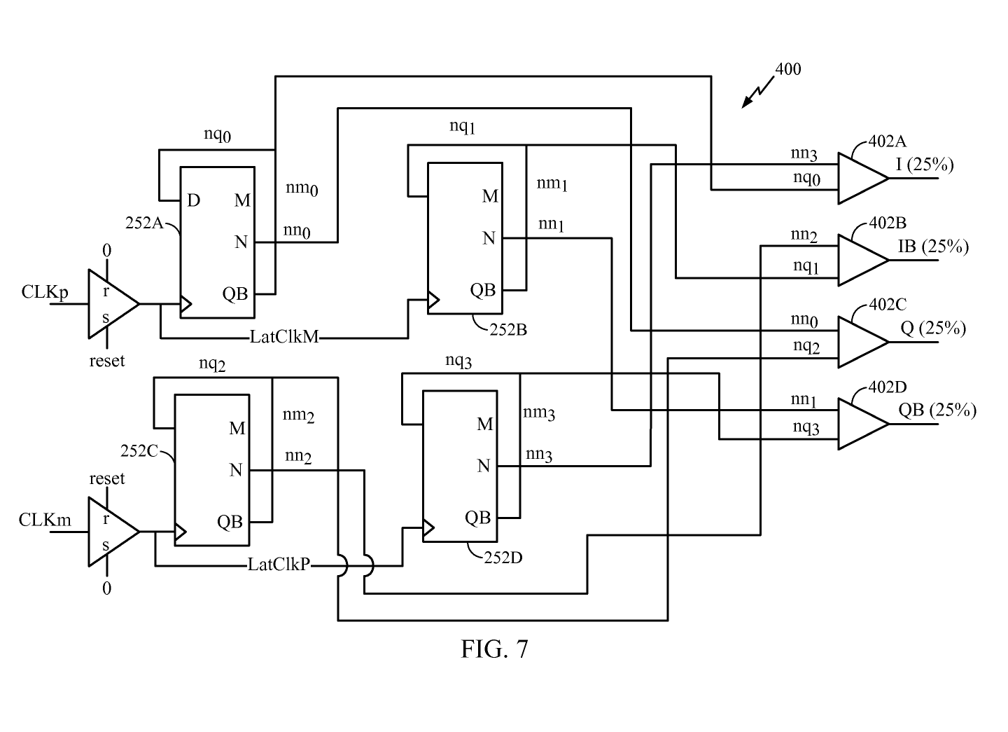

FIG. 7 illustrates a device 400, according to an exemplary embodiment of the present invention. Device 300 includes a plurality of dynamic logic cells 252A-D coupled to a plurality of dynamic inverters 402A-402D. More specifically, device 400 includes a dynamic inverter 402A configured to receive a signal nn₃ from dynamic logic cell 252D and a signal nq₀ from dynamic logic cell 252A. Further, dynamic inverter 402A may be configured to convey a clock signal I having a twenty-five percent duty cycle. In addition, device 400 includes a dynamic inverter 402b configured to receive a signal nn₂ from dynamic logic cell 252C and a signal nq₁ from dynamic logic cell 252B. Dynamic inverter 402b may also be configured to convey a clock signal IB having a twenty-five percent duty cycle. Moreover, device 300 includes a dynamic inverter 402C configured to receive a signal nn₀ from dynamic logic cell 252A and a signal nq₂ from dynamic logic cell 252C. Further, dynamic inverter 402C may be configured to convey a clock signal Q having a twenty-five percent duty cycle. Furthermore, device 300 includes a dynamic inverter 402D configured to receive a signal nn₁ from dynamic logic cell 252B and a signal nq₃ from dynamic logic cell 252D. Dynamic inverter 402D may be configured to convey a clock signal QB having a twenty-five percent duty cycle.

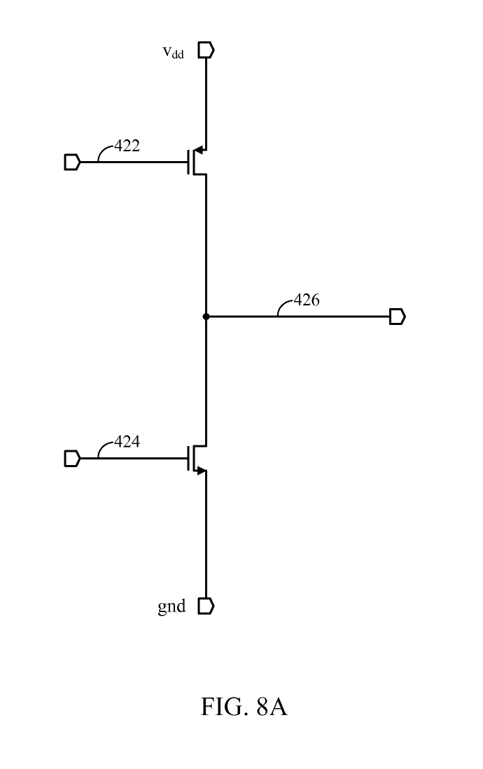

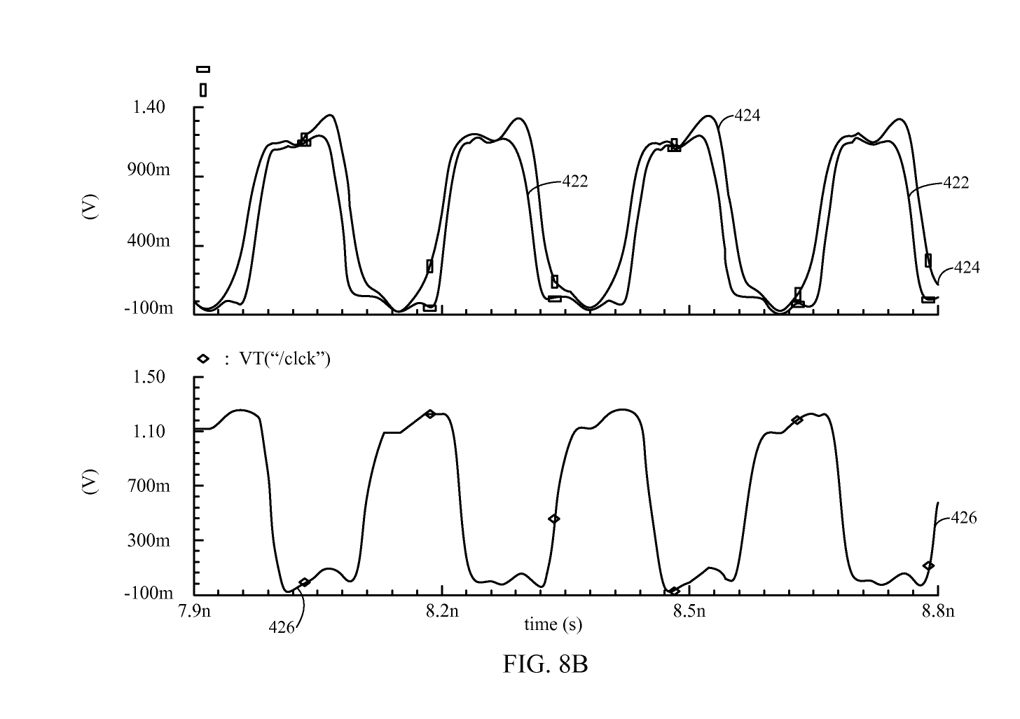

FIG. 8A illustrates a circuit diagram of a dynamic inverter 420. As an example, each dynamic inverter 402A-402D (see FIG. 7) may comprise dynamic inverters 420. Dynamic inverter 420 includes a first input signal 422, which is conveyed to a gate of a transistor. Moreover, dynamic inverter 420 includes a second input signal 424, which is conveyed to a gate of another transistor. Dynamic inverter 420 in configured to convey an output clock signal 426. With reference to FIG. 8B, waveforms of first input signal 422, second input signal 424, and output clock signal 426 are illustrated. Signal 422, which is conveyed from a dynamic logic cell, may have a duty cycle is larger than a duty cycle of signal 424, which is conveyed from another dynamic logic cell. Furthermore signal 422 is time aligned with signal 424 such that signal 422 is always at logic 1 when signal 424 is at logic 1. As a result, when output node 426 charges from logic 0 to logic 1 through the PMOS transistor, the NMOS transistor always stays turned-off. On the other hand, when output node 426 discharges from logic 1 to logic 0 through the NMOS transistor, the PMOS always stays turned-off. This arrangement offers power savings in the LO path because any short circuit power dissipation, which results in the condition when both PMOS and NMOS are conducting simultaneously, is completely eliminated.

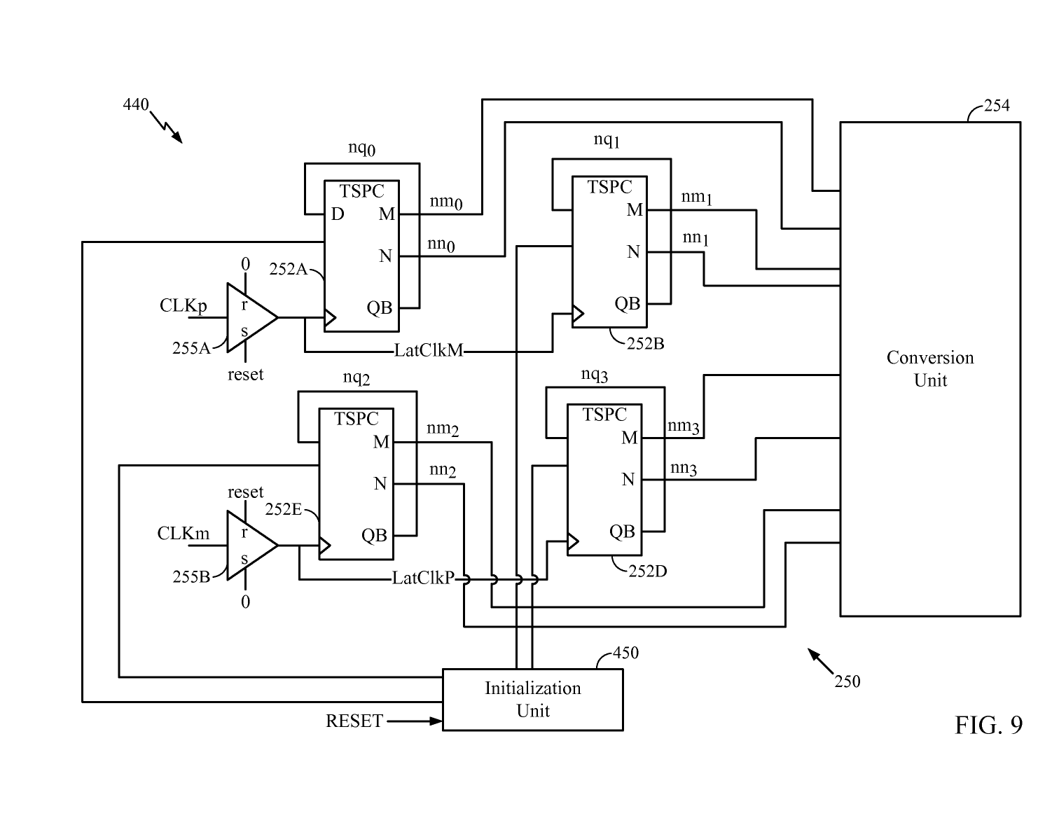

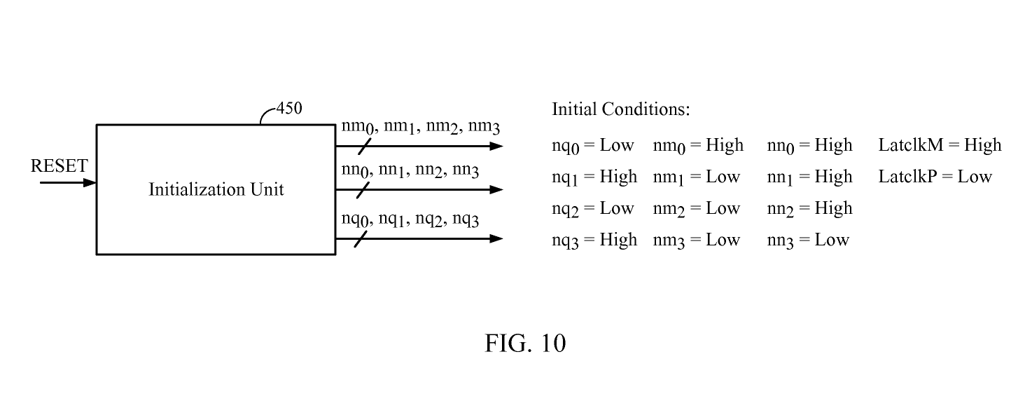

FIG. 9 illustrates a device 440 including device 250 coupled to an initialization unit 450, according to an exemplary embodiment of the present invention. As described more fully with reference to FIG. 10, initialization unit 450 may be configured to receive a reset signal RESET and convey a plurality of signals to each dynamic logic cell 252A-D for pre-charging nodes within each dynamic logic cell 252A-D.

FIG. 10 illustrates initialization unit 450, in accordance with another exemplary embodiment of the present invention. Initialization unit 450 may be configured to receive reset signal RESET. Further, in response to receipt of a RESET signal initialization unit 450 may be configured to convey a plurality of initialization signals to each of a plurality of dynamic logic cells. As one example, initialization unit 450 may be configured to convey a plurality of initialization signals to each of dynamic logic cells 252A-D, which are illustrated in FIGS. 5-7. More specifically, as one example, initialization unit 450 may convey one or more signals to dynamic logic cell 252A for pre-charging a voltage at output N, pre-charging a voltage at output M, and pre-charging a voltage at output QB. Accordingly, with reference to FIGS. 3, 9, and 10, initialization unit 450 may be configured to pre-charge a voltage at node A, pre-charge a voltage at node B, and pre-charge a voltage at output QB for each dynamic logic cell 252A-D.

According to one exemplary embodiment of the present invention, initialization unit 450 may be configured to initialize (i.e., pre-charge) signals nq₁, nq₃, nm₀, nn₀, nn₁, nn₂, and LatClkM to a high state. Further, initialization unit 450 may be configured to initialize (i.e., pre-charge) signals nq₀, nq₂, nm₁, nm₂, nm₃, nn₃, and LatClkP to a low state.

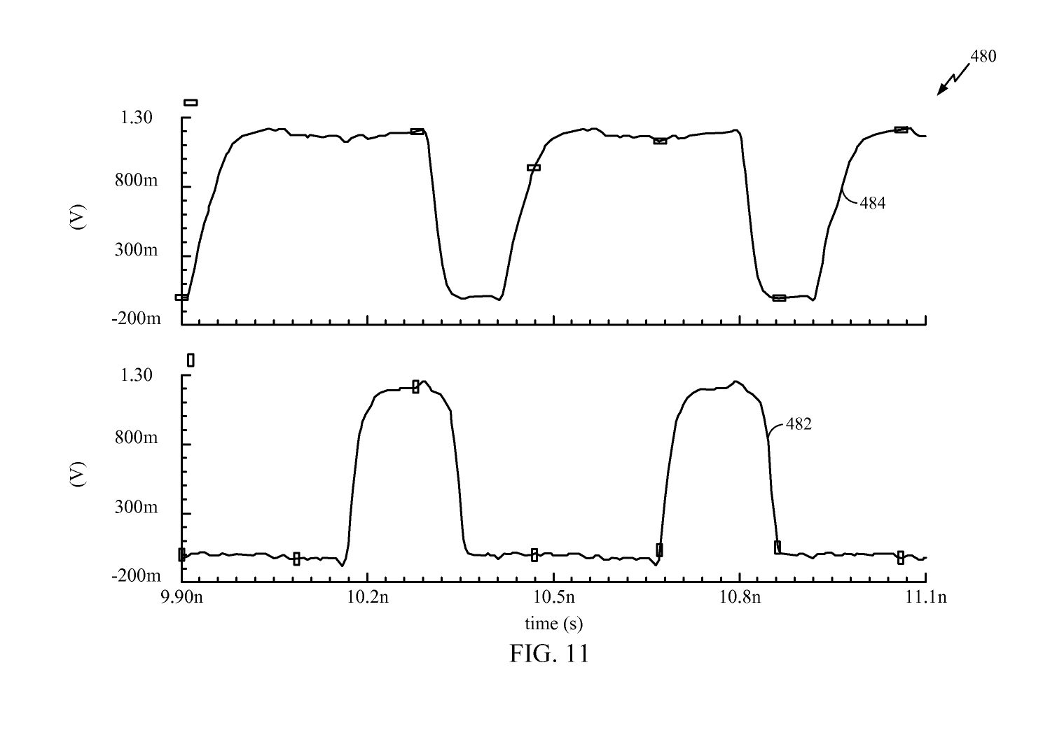

FIG. 11 is a plot 480 illustrating a waveform 482, which may be utilized as an NMOS driver, and a waveform 484, which may utilized as a PMOS driver (another LO phase) for the dynamic inverter illustrated in FIG. 8A. As an example, with reference to FIG. 7, waveform 482 maybe signal nq0 and waveform 484 maybe signal nn3 driving dynamic inverter 402A

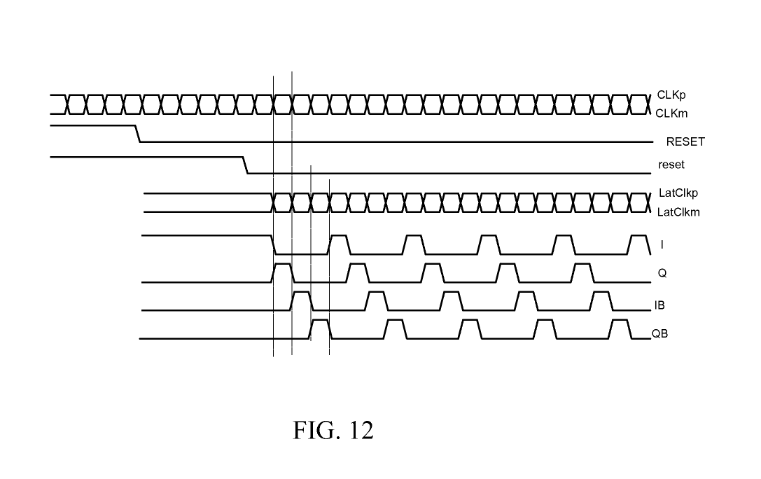

FIG. 12 is a timing plot 500 illustrating various waveforms associated with device 400, which is illustrated in FIG. 7. Waveform “reset” is an example of a signal that is conveyed to gating buffers 255A and 255B. Waveforms LatClkP and LatClkM in timing plot 500 represent the outputs of the gating buffers 255B and 255A respectively upon initialization by the reset signal. Waveform “RESET” is an example of a signal that is conveyed to initialization unit 450 (see FIGS. 9 and 10). It is noted that, according to one embodiment of the present invention, the RESET signal, which is applied to internal nodes of each dynamic logic cell, may “fall” prior to the “reset” signal that is applied to a gating buffer. Furthermore, a gating buffer may be configured such that upon release of a reset signal applied thereto, adequate time exists for its output node to attain a final value before toggling begins. In relation to FIG. 7 and FIG. 12, this implies that buffers 255A-B are configured such that upon the release of the “reset” signal the output signals LatClkP and LatClkM are held at their initialization value for an adequate time before they start toggling in response to input CLKp and CLKm signals respectively. In addition, waveforms “I”, “IB”, “Q” and “QB” depict the quadrature output signals, each having a twenty-five percent duty cycle representing outputs of dynamic buffers 402A-402D in FIG. 7

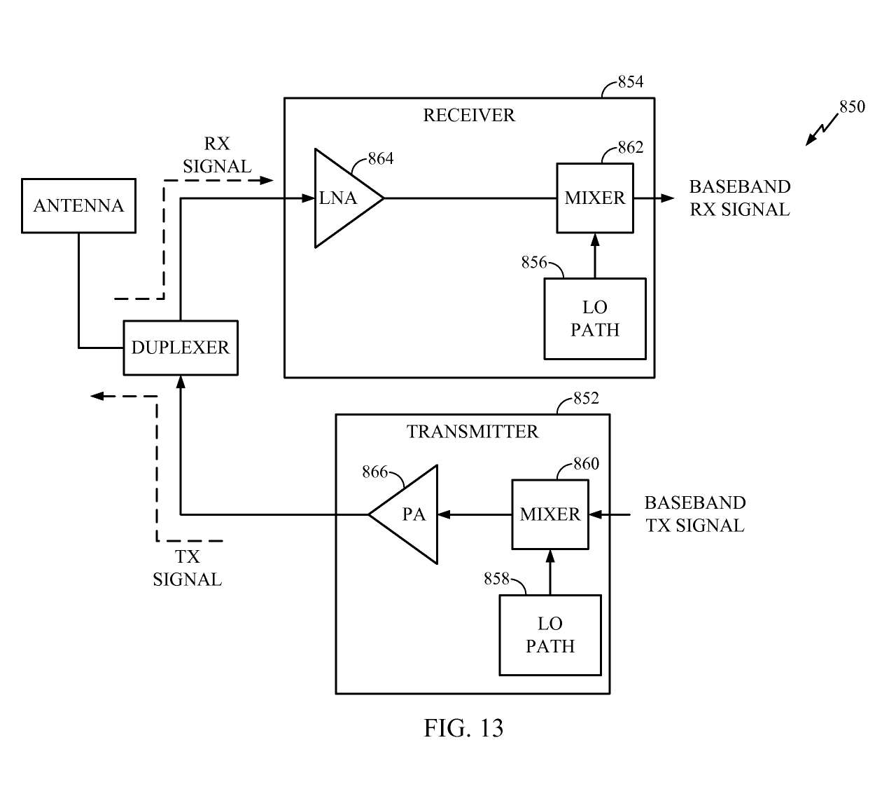

FIG. 13 illustrates a transceiver 850 including a transmitter 852, which includes a LO path 858, a mixer 860, and a power amplifier 866. According to an exemplary embodiment of the present invention, LO path 858 may include device 440 illustrated in FIG. 9. As such, quadrature symmetric clock signals having twenty-five percent duty cycles may be conveyed from LO path 858 to mixer 860. Further transceiver 850 includes a receiver 854, which comprises a LO path 856, a mixer 862, and a low-noise amplifier (LNA) 864. According to an exemplary embodiment of the present invention, LO path 856 may also include device 440 illustrated in FIG. 9. As such, quadrature symmetric clock signals having twenty-five percent duty cycles may be conveyed from LO path 856 to mixer 862.

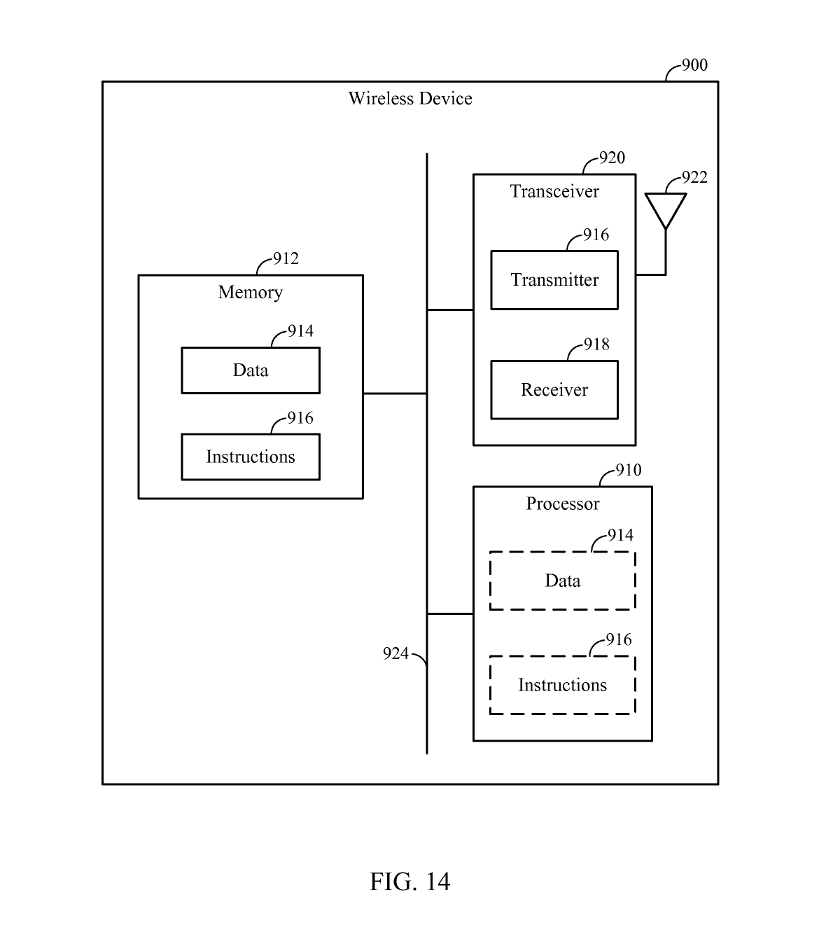

FIG. 14 illustrates a wireless device 900, which may comprise, for example only, a mobile device or a base station. More specifically, for example, wireless device 900 may be a mobile device including a transmitter, a receiver, or both. Wireless device 900 includes a processor 910, which may be a general purpose single- or multi-chip microprocessor (e.g., an ARM), a special purpose microprocessor (e.g., a digital signal processor (DSP)), a microcontroller, a programmable gate array, etc. Processor 910 may be referred to as a central processing unit (CPU). Although just a single processor is shown in the wireless device 900 of FIG. 14, in an alternative configuration, a combination of processors (e.g., an ARM and DSP) could be used.

Wireless device 900 also includes memory 912, which may be any electronic component capable of storing electronic information. Memory 912 may be embodied as random access memory (RAM), read only memory (ROM), magnetic disk storage media, optical storage media, flash memory devices in RAM, on-board memory included with the processor, EPROM memory, EEPROM memory, registers, and so forth, including combinations thereof. Data 914 and instructions 916 may be stored in the memory 912. Instructions 916 may be executable by the processor 910 to implement the methods disclosed herein. Executing the instructions 916 may involve the use of data 914 that is stored in memory 912.

Wireless device 900 further includes a transmitter 916 and a receiver 918 to allow transmission and reception of signals between wireless device 900 and a remote location. It is noted that transmitter 916 may comprise transmitter 852 illustrated in FIG. 13. Further, receiver 918 may comprise receiver 854 illustrated in FIG. 13. Transmitter 916 and receiver 918 may be collectively referred to as a transceiver 920, which may comprise transceiver 850 of FIG. 13. An antenna 922 may be electrically coupled to transceiver 920. Wireless device 900 may also include multiple transmitters, multiple receivers, multiple transceivers and/or multiple antenna.

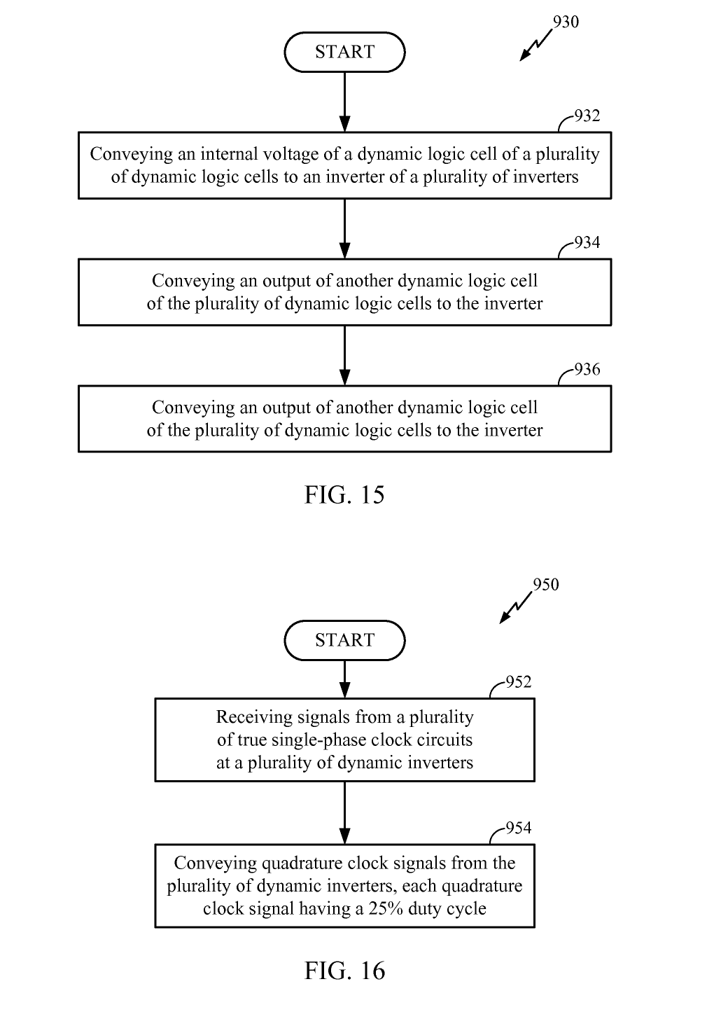

The various components of the wireless device 900 may be coupled together by one or more buses, which may include a power bus, a control signal bus, a status signal bus, a data bus, etc. For the sake of clarity, the various buses are illustrated in FIG. 15 as a bus system 924.

FIG. 15 is a flowchart illustrating a method 930, in accordance with one or more exemplary embodiments. Method 930 may include conveying an internal voltage of a dynamic logic cell of a plurality of dynamic logic cells to an inverter of a plurality of inverters (depicted by numeral 932). Method 930 may also include conveying an output of another dynamic logic cell of the plurality of dynamic logic cells to the inverter (depicted by numeral 934). Further, method 930 may include conveying a clock signal from the inverter (depicted by numeral 936).

FIG. 16 is a flowchart illustrating another method 950, in accordance with one or more exemplary embodiments. Method 950 may include receiving signals from a plurality of true single-phase clock circuits at a plurality of dynamic inverters (depicted by numeral 952). Further, method 950 may include conveying quadrature clock signals from the plurality of dynamic inverters, each quadrature clock signal having a twenty-five percent duty cycle (depicted by numeral 954).

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the exemplary embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the exemplary embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the exemplary embodiments shown herein but is to be accorded the widest scope consistent with the principles and novel features disclosed herein.

What is claimed is:

1. A device, comprising:
a plurality of true single-phase clock circuits; and
a plurality of dynamic inverters, each dynamic inverter of the plurality of dynamic inverters configured to receive at least one signal from an internal node of a true single-phase clock circuit of the plurality of true single-phase clock circuits.

2. The device of claim 1, each dynamic inverter of the plurality of dynamic inverters configured to convey a signal having a twenty-five percent duty cycle.

3. The device of claim 1, the plurality of dynamic inverters comprising four dynamic inverters configured to convey quadrature symmetric clock signals.

4. The device of claim 1, each true single-phase clock circuit configured to receive at least one initialization signal for pre-charging at least one signal at an internal node thereof.

5. The device of claim 1, further comprising an initialization unit for conveying initialization signals to each of the true single-phase clock circuits.

6. The device of claim 1, the initialization unit configured to:
receive a reset signal;
convey a first signal to each true single-phase clock circuit for pre-charging a voltage at a first internal node of each true single-phase clock circuit;
convey a second signal to each true single-phase clock circuit for pre-charging a voltage at a second internal node of each true single-phase clock circuit; and
convey a third signal to each true single-phase clock circuit for pre-charging a voltage at an output of each true single-phase clock circuit.

7. The device of claim 1, each dynamic inverter of the plurality of dynamic inverters configured to receive a first signal from a first true single-phase clock circuit of the plurality of true single-phase clock circuits and a second signal from a second true single-phase clock circuit of the plurality of true single-phase clock circuits.

8. The device of claim 1, each dynamic inverter of the plurality of dynamic inverters configured to receive a first signal from an internal node of a first true single-phase clock circuit of the plurality of true single-phase clock circuits and a second signal from an output of a second true single-phase clock circuit of the plurality of true single-phase clock circuits.

9. A device, comprising:
a plurality of dynamic logic cells; and
a plurality of dynamic inverters, each dynamic inverter of the plurality of dynamic inverters coupled to at least two dynamic logic cells of the plurality of dynamic logic cells and configured to output a clock signal having a twenty-five percent duty cycle.

10. The device of claim 9, the plurality of dynamic inverters comprising four dynamic inverters configured to convey quadrature symmetric clock signals.

11. The device of claim 9, further comprising an initialization unit for conveying initialization signals to each of the dynamic logic cells for pre-charging nodes therein to a desired voltage.

12. The device of claim 11, the initialization unit further configured for conveying the initialization signals upon receipt of a RESET signal.

13. The device of claim 9, each dynamic inverter configured to convey a signal having a twenty-five percent duty cycle to a mixer within a local oscillator path.

14. The device of claim 9, the plurality of dynamic logic cells comprising a plurality of true single-phase clock circuit.

15. The device of claim 9, each dynamic inverter of the plurality of dynamic inverters configured to receive a first signal from a first dynamic logic cell of the plurality of dynamic logic cells and a second signal from a second dynamic logic cell of the plurality of dynamic logic cells.

16. A method, comprising:
conveying an internal voltage of a dynamic logic cell of a plurality of dynamic logic cells to a dynamic inverter of a plurality of dynamic inverters;
conveying an output of another dynamic logic cell of the plurality of dynamic logic cells to the dynamic inverter; and
conveying a clock signal from the dynamic inverter.

17. The method of claim 16, the conveying a clock signal comprising conveying a clock signal having a twenty-five percent duty cycle.

18. The method of claim 16, further comprising pre-charging an internal node of each dynamic logic cell.

19. A method, comprising:
receiving signals from a plurality of true single-phase clock circuits at a plurality of dynamic inverters; and
conveying quadrature clock signals from the plurality of dynamic inverters, each quadrature clock signal having a twenty-five percent duty cycle.

20. The method of claim 19, receiving signals comprising receiving a first signal from an internal node of a first true single-phase clock circuit of the plurality of true single-phase clock circuits and a second signal from an output of a second true single-phase clock circuit of the plurality of true single-phase clock circuits at each dynamic inverter of the plurality of dynamic inverters.

21. The method of claim 19, further comprising initializing a plurality of voltages at each true single-phase clock circuit of the plurality of true single-phase clock circuits.

22. The method of claim 21, initializing a plurality of voltages at each true single-phase clock circuit comprising initializing at least one internal voltage of each true single-phase clock circuit and an output voltage of each true single-phase clock circuit.

23. A device, comprising:
means for receiving an internal voltage of a dynamic logic cell of a plurality of dynamic logic cells;
means for receiving an output of another dynamic logic cell of the plurality of dynamic logic cells to the inverter; and
means for generating a clock signal based on the internal voltage of the dynamic logic cell and the output of the another dynamic logic cell.

24. The device of claim 23, the means for generating a clock signal based on the internal voltage of the dynamic logic cell and the output of the another dynamic logic cell comprising means for generating a clock signal having a twenty-five percent duty cycle.

25. A device, comprising:
means for receiving signals from a plurality of true single-phase clock circuits; and
means for conveying quadrature clock signals, each quadrature clock signal having a twenty-five percent duty cycle.

26. A device, comprising:
a plurality of true single-phase clock circuits; and
a plurality of static inverters, each static inverter of the plurality of static inverters configured to receive a signal from an internal node of each true single-phase clock circuit of the plurality of true single-phase clock circuits.

27. A device, comprising:
a plurality of true single-phase clock circuits; and
a plurality of static buffers, each static buffer of the plurality of static buffers configured to receive at least one signal from an internal node of each true single-phase clock circuit of the plurality of true single-phase clock circuits.

28. A method, comprising:
receiving signals from internal nodes of plurality of true single-phase clock circuits at a conversion unit; and
conveying quadrature clock signals from the conversion unit, each quadrature clock signal having a twenty-five percent duty cycle.
